(19) United States
(12) Patent Application Publication
(10) Pub. No.: US 2024/0385754 A1
(43) Pub. Date: Nov. 21, 2024

(54) Devices and Methods for Preventing Memory Failure in Electronic Devices

(71) Applicant: Intel Corporation, Santa Clara, CA (US)

(72) Inventors: Zhenglong WU, Shanghai (CN); Daocheng BU, Shanghai (CN); Dujian WU, Shanghai (CN); Yufu LI, Shanghai (CN); Vincent ZIMMER, Issaquah, WA (US)

(21) Appl. No.: 18/570,674

(22) PCT Filed: Dec. 14, 2021
(86) PCT No.: PCT/CN2021/137788

§ 371 Date: Dec. 15, 2023

(51) Int. Cl. G06F 3/06

(52) U.S. Cl. CPC G06F 3/0616; G06F 3/0653; G06F 3/0679

(57) ABSTRACT

Various examples relate to a control apparatus, a control device, a method, and a computer program for managing repair of a memory circuitry, and to a corresponding computing device. The control apparatus comprises processing circuitry configured to determine a score of a memory failure probability of at least one memory cell of the memory circuitry and trigger a repair procedure of the at least one memory cell of the memory circuitry when the score reaches a threshold.

### BACKGROUND

Errors in dynamic random-access memory (DRAM) are a common form of hardware failure in modern compute clusters. Failures are generally costly both in terms of hardware replacement cost and service disruption. Both end users (such as Customer Service) and Original Equipment Manufacturers (OEMs) have high demand on effective memory error handling.

### BRIEF DESCRIPTION OF THE FIGURES

Some examples of control apparatuses and/or methods will be described in the following by way of example only, and with reference to the accompanying figures, in which

FIG. 1 shows a schematic overview of approaches to failure handling in memory

FIG. 2a shows a schematic diagram of an example of a control apparatus or control device for managing repair of a memory circuitry;

FIG. 2b shows a schematic diagram of an example of computing device comprising a control apparatus or control device for managing repair of a memory circuitry;

FIG. 2c shows a flow chart of an example of a method for managing repair of a memory circuitry;

FIG. 3 shows a schematic diagram of an example of a machine-learning based training of a predictor for predicting uncorrectable errors (UCEs) and/or correctable errors (CEs);

FIG. 4 shows a schematic diagram of Post Package Repair (PPR) being triggered by a failed row in a memory device;

FIG. 5a shows a schematic diagram of boot time PPR;

FIG. 5b shows a schematic diagram of runtime PPR;

FIG. 6 shows a schematic diagram illustrating the application of memory failure prediction to runtime PPR;

FIG. 7 shows a flow chart of an example of the proposed concept;

FIG. 8 shows a schematic diagram of another example of a machine-learning based training of a predictor for predicting uncorrectable errors and/or correctable errors;

FIG. 9 shows a schematic diagram of a relationship between an UCE/CE predictor the runtime PPR;

FIG. 10 shows a schematic diagram of an application of the proposed concept in a computer system;

FIG. 11 shows a schematic overview of processor/chipset modules; and

FIG. 12 shows a schematic diagram of a computing system.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

In the following description, specific details are set forth, but examples of the technologies described herein may be practiced without these specific details. Well-known circuits, structures, and techniques have not been shown in detail to avoid obscuring an understanding of this description. “An example/example,” “various examples/examples,” “some examples/examples,” and the like may include features, structures, or characteristics, but not every example necessarily includes the particular features, structures, or characteristics.

Some examples may have some, all, or none of the features described for other examples. “First,” “second,” “third,” and the like describe a common element and indicate different instances of like elements being referred to. Such adjectives do not imply element item so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform, or resource, even though the instructions contained in the software or firmware are not actively being executed by the system, device, platform, or resource.

The description may use the phrases “in an example/example,” “in examples/examples,” “in some examples/examples,” and/or “in various examples/examples,” each of which may refer to one or more of the same or different examples. Furthermore, the terms “comprising,” “including,” “having,” and the like, as used with respect to examples of the present disclosure, are synonymous.

Various examples of the present disclosure relate to a concept for preventing memory failure at run time based on memory failure predication and PPR (Post-Package Repair).

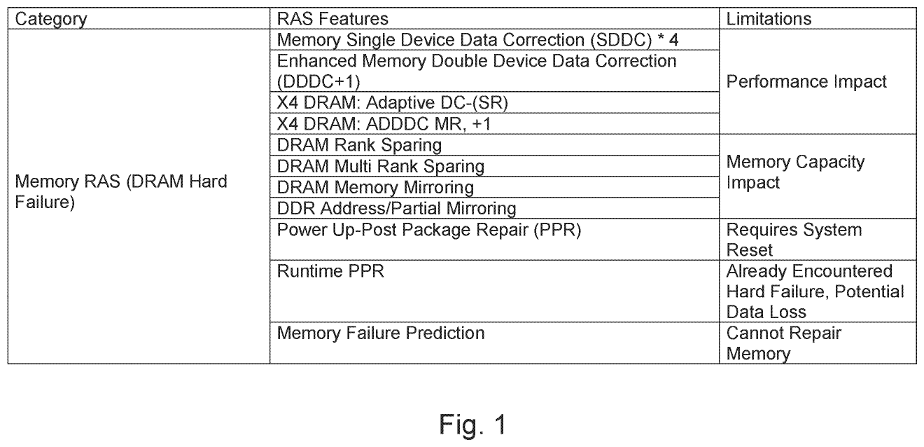

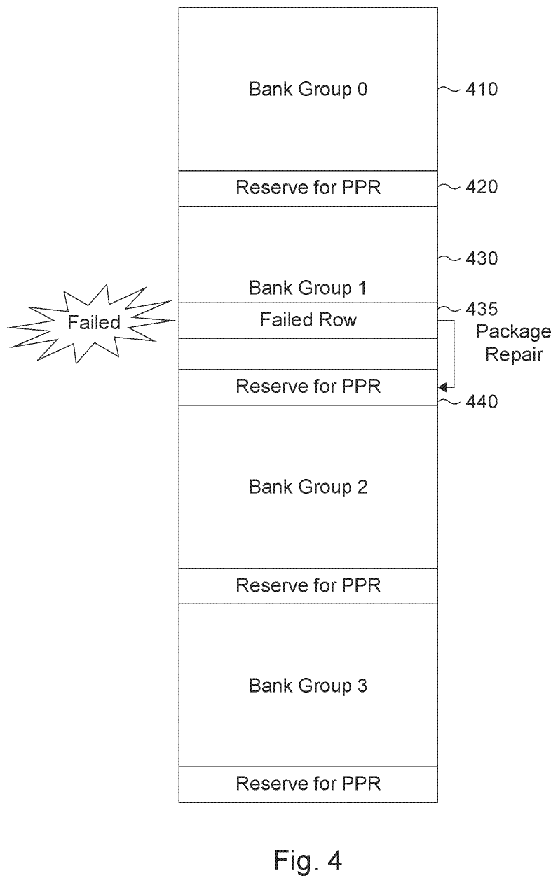

Memory errors are common hardware failures. When a memory error occurs, generally, the following measures may be taken to resolve the issue. FIG. 1 shows a schematic overview of approaches to failure handling in memory. FIG. 1 may show memory RAS (Reliability, Availability and Serviceability) features for data errors. For example, Single Device Data Correction (SDDC), Enhanced Memory Double Device Data Correction (DDDC), Adaptive Data Correction-Single Region (ADC SR), or Adaptive Double Device Data Correction-Multi Region (ADDDC MR) may be used, which may have a performance impact because memory need to work in lock step mode. Alternatively, memory mirroring (e.g., DRAM Memory mirroring and/or DDR4 (Double Data Rate 4) address/partial mirroring) and sparing (e.g., DRAM rank sparing or DRAM multi rank sparing) may be used, which may reduce the memory capacity and consequently impact the performance. As an alternative, the power up-Post Package Repair (PPR) may be used, which may impact system availability. Power up-PPR is illustrated in FIG. 5a, for example. In some examples, Runtime-PPR may be used, which can repair the failure, but the repair might happen when the failure is happening, leading to potential data loss, and might still impacts the system service and user. Runtime-PPR is illustrated in FIG. 5b, for example. Furthermore, memory failure prediction may be used, which is merely a prediction and does not actually repair the DRAM. Alternatively, or additionally, not shown in FIG. 1, the DIMM may be replaced once a failure occurs, which will incur a hardware and service cost.

In the following, a control apparatus 20 and a corresponding control device 20, method and computer program are introduced, which are suitable for managing repair of a memory circuitry before a portion of the memory circuitry being repaired fails.

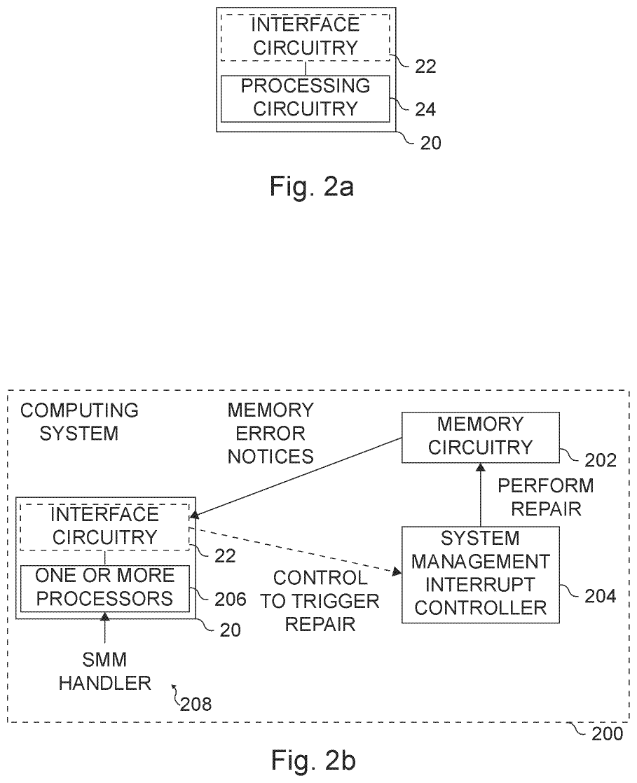

FIG. 2a shows a schematic diagram of an example of a control apparatus 20 or control device 20 for managing repair of a memory circuitry 202 of a computing device 200 (as shown in FIG. 2b). The control apparatus 20 comprises circuitry that is configured to provide the functionality of the control apparatus 20. For example, the control apparatus 20 of FIG. 2a comprises (optional) interface circuitry 22 and processing circuitry 24. For example, the processing circuitry 24 may be coupled with the interface circuitry 22. For example, the processing circuitry 24 may be configured to provide the functionality of the control apparatus, in conjunction with the interface circuitry 22 (for exchanging information, e.g., for accessing the memory circuitry, or with other components of the computer system 200, such as a system management interrupt (SMI) controller 204). For example, as shown in FIG. 2b, the processing circuitry 24 may be implemented by one or more processors 206 of the computing device. Likewise, the control device 20 may comprise means that is/are configured to provide the functionality of the control device 20. The components of the control device 20 are defined as component means, which may correspond to, or implemented by, the respective structural components of the control apparatus 20. For example, the control device 20 of FIG. 2a comprises means for processing 24, which may correspond to or be implemented by the processing circuitry 24 and (optional) means for communicating 22, which may correspond to or be implemented by the interface circuitry 22.

The processing circuitry 24 or means for processing 24 is configured to determine a score of a memory failure probability of at least one memory cell of the memory circuitry 202. The processing circuitry 24 or means for processing 24 is configured to trigger a repair procedure of the at least one memory cell of the memory circuitry when the score reaches a threshold.

FIG. 2b shows a schematic diagram of an example of computing device comprising the control apparatus 20 or control device 20 introduced in connection with FIG. 2a. The computing device comprises the memory circuitry, the control apparatus 20 or control device 20, and optionally, the SMI controller 204. As shown in FIG. 2b, one or more processors 206 of the computing device 200 may be used to implement the processing circuitry 24 or means for processing 24 of the control apparatus 20 or control device 20.

FIG. 2c shows a flow chart of an example of a corresponding method for managing repair of a memory circuitry. For example, the method may be performed by the computing device 200 shown in FIG. 2b, e.g., by the control apparatus 20 or control device 20 of the computing device 200. The method comprises determining 230 the score of a memory failure probability of at least one memory cell of the memory circuitry. The method comprises triggering 250 a repair procedure of the at least one memory cell of the memory circuitry when the score reaches a threshold.

In the following, the features of the control apparatus 20, of the control device 20, of the computing device 200, of the method and of a corresponding computer program are introduced in connection with the control apparatus 20 and computing device 200 of FIGS. 2a and 2b. Features introduced in connection with the control apparatus 20 or computing device 20 may likewise be introduced in the corresponding control device 20, method and computing program.

Various examples of the present disclosure relate to devices, such as the control apparatus, control device and computing device of FIGS. 2a to 2b, and methods, such as the method of FIG. 2c, for preventing memory failure in electronic devices. In contrast to many other concepts, the present concept is primarily targeted at preventing memory failure, by predicting impending memory failure and using the self-repair functionality of the memory circuitry to preemptively repair the memory circuitry before the failure occurs.

The present concept is based on predicting impending hard memory failures of memory circuitry before they occur. For this purpose, a probability-based approach is used, where a score of the memory failure probability of at least one memory cell of the memory circuitry 202 is determined. In other words, the processing circuitry is configured to estimate or predict the probability, that at least one memory cell of the memory circuitry fails, e.g., that it fails in a pre-defined time interval relative to current time, such as the next 12 hours, the next day, the next week etc.

The score of the memory failure probability is determined for at least one memory cell of the memory circuitry. For example, the score of the memory failure probability may be determined separately for different memory cells or sets of memory cells of the memory circuitry. For example, the memory circuitry may be memory circuitry that is contained in Dual Inline Memory Modules (DIMMs). The score may be associated with a memory location of the memory circuitry, with the memory location being identified by at least one of a DIMM identifier, a rank, a bank, a row, a column, and a cell. Portions of memory of a DIMM memory circuitry can be accessed/distinguished using the DIMM identifier (for identifying the DIMM, using the rank (with each rank comprising one or more Dynamic Random-Access Memory, DRAM, chips), using the bank (which is a block of memory of a DRAM Chip), using rows and columns (which are used to subdivide a bank into a grid of rows and columns), and cells (e.g., a combination of row and columns). In some examples, the score of the memory failure probability may be determined separately for each cell. Alternatively, the score of the memory failure probability may be determined with a lower granularity, e.g., separately for each row, as will become evident in the following. In this context, the score of the memory failure probability may be a numerical value that represents the probability, that the at least one memory cell (e.g., that the row) is going to fail in a pre-determined time interval relative to the current time.

To determine the score of the memory failure probability, at least two components may be used—information on errors occurring at the respective memory cells, and a predictor that can be used to predict the score of the memory failure probability based on the errors. In some examples, additional information, such as temperature, age, positional relationships between errors may be taken into account as well.

In general, the information on the errors may be gathered by logging the errors, and in particular the correctable errors and uncorrectable errors, being generated by the memory circuitry at the desired granularity. For example, the processing circuitry may be configured to log memory error notices from the memory circuitry, and to determine the score based on the memory error notices. Accordingly, as further shown in FIG. 1c, the method may comprise logging 220 memory error notices from the memory circuitry and determining 230 the score based on the memory error notices. For example, the processing circuitry 24 may be configured to collect and accumulate the memory error notices, e.g., with the granularity required for determining the score of the memory failure probability, e.g., with the granularity required as input for the predictor. For example, the processing circuitry 24 may be configured to log the memory error notices with a per-memory-cell granularity or with a per-row granularity.

In some cases, memory errors, which are later used for predicting the impending failure of portions of the memory circuitry, primarily occur when the computing device is under heavy load, e.g., if many memory read and memory write operations are performed at the same time. To trigger such errors (and thus identify portions of memory that are likely to fail), the memory circuitry may be “stressed”, and the errors that occur during this tress test may be logged and used to determine the score. For example, the processing circuitry is configured to trigger a memory stress test of the memory circuitry, and to determine the score based on memory error notices generated during or after the memory stress test. Accordingly, as further shown in FIG. 1c, the method may comprise triggering 210 a memory stress test of the memory circuitry and determining 230 the score based on memory error notices generated during or after the memory stress test.

As outlined above, a predictor may be used to determine the score. In particular, a trained predictor may be used, which is machine-learning model that is trained to determine the score based on a historical memory error dataset. In other words, the processing circuitry may be configured to process the memory error notices of the memory circuitry with a trained predictor to determine the score. Accordingly, as further shown in FIG. 1c, the method may comprise processing 225 the memory error notices of the memory circuitry with a trained predictor to determine the score. In particular, the logged memory error notices may be provided at an input of the trained predictor, and an output of the trained predictor may be used to determine the score. For example, the score may correspond to the output of the trained predictor, or the score may be derived from the output of the trained predictor.

As outlined above, in some examples, the trained predictor is a trained machine-learning model that is trained based on a historical memory error dataset. To illustrate the concept of “training” a “machine-learning model”, in the following, a short introduction to machine learning is given. Machine learning refers to algorithms and statistical models that computer systems may use to perform a specific task without using explicit instructions, instead relying on models and inference. For example, in machine-learning, instead of a rule-based transformation of data, a transformation of data may be used, that is inferred from an analysis of historical and/or training data. For example, the content of images may be analyzed using a machine-learning model or using a machine-learning algorithm. In order for the machine-learning model to analyze the content of an image, the machine-learning model may be trained using training images as input and training content information as output. By training the machine-learning model with a large number of training images and associated training content information, the machine-learning model “learns” to recognize the content of the images, so the content of images that are not included of the training images can be recognized using the machine-learning model. The same principle may be used for other kinds of sensor data as well, such as the memory error notices. By training a machine-learning model using training sensor data and a desired output, the machine-learning model “learns” a transformation between the sensor data (e.g., the memory error notices) and the output, which can be used to provide an output based on non-training sensor data provided to the machine-learning model.

Machine-learning models are trained using training input data. The examples specified above use a training method called “supervised learning”. In supervised learning, the machine-learning model is trained using a plurality of training samples, wherein each sample may comprise a plurality of input data values, and a plurality of desired output values, i.e., each training sample is associated with a desired output value. By specifying both training samples and desired output values, the machine-learning model “learns” which output value to provide based on an input sample that is similar to the samples provided during the training. Apart from supervised learning, semi-supervised learning may be used. In semi-supervised learning, some of the training samples lack a corresponding desired output value. Supervised learning may be based on a supervised learning algorithm, e.g., a classification algorithm, a regression algorithm or a similarity learning algorithm. Classification algorithms may be used when the outputs are restricted to a limited set of values, i.e., the input is classified to one of the limited set of values. Regression algorithms may be used when the outputs may have any numerical value (within a range). Similarity learning algorithms are similar to both classification and regression algorithms but are based on learning from examples using a similarity function that measures how similar or related two objects are.

In the present case, supervised learning may be used to train the machine-learning model of the trained predictor. For example, as outlined above, the trained predictor may be trained based on a historical memory error dataset. The historical memory error dataset may comprise fault data of failed memory circuits, with the fault data comprising fault location data. In other words, the fault data may comprise information on the rank, bank, row, column and/or cell where the respective fault has occurred. In this context, the term “fault” refers to hard memory failures, i.e., permanent hardware failures of portions of memory. In addition, the fault data may comprise information on memory errors that have occurred prior to failure of the portion of the memory circuit. The trained predictor may be trained by generating a plurality of training input samples each comprising information on (a number of) correctable and/or uncorrectable errors and information on a location of the correctable or uncorrectable errors. In addition, the desired output may be specified, with the desired output comprising information on the location of faults, i.e., hard memory failures, which have occurred in the respective memory circuitry. Based on the training samples and the corresponding desired outputs, the trained predictor may be trained to determine the score, or a value that is indicative of the score, based on an input comprising the comprising information on (a number of) correctable and/or uncorrectable errors and information on a location of the correctable or uncorrectable errors, e.g., for each memory cell or row.

In some examples, additional information may be used to improve the prediction. For example, as outlined above, the processing circuitry may be configured to determine the score based on information such as a number of errors, a number of correctable errors, a number of uncorrectable errors, e.g., with each error or number of errors being associated with a location of the error in the memory circuitry. In addition, the processing circuitry may be configured to determine the score based on at least one of a temperature of the memory circuitry, a manufacturing data of the memory circuitry, and a repair history of the memory circuitry. For example, at least one of the temperature of the memory circuitry, the manufacturing data of the memory circuitry, and the repair history of the memory circuitry may be comprised in the fault data, and at least one of the temperature of the memory circuitry, the manufacturing data of the memory circuitry, and the repair history of the memory circuitry may be included as information in the training samples. Accordingly, the processing circuitry may be configured to provide one or more the number of errors, the number of correctable errors, the number of uncorrectable errors the temperature of the memory circuitry, the manufacturing data of the memory circuitry, and the repair history of the memory circuitry may be comprised in the fault data as input to the trained predictor, and to determine the score based on the output of the trained predictor. For example, the trained predictor may be trained to perform regression analysis, so that the trained predictor yields a numerical value that can be used as score or to derive the score.

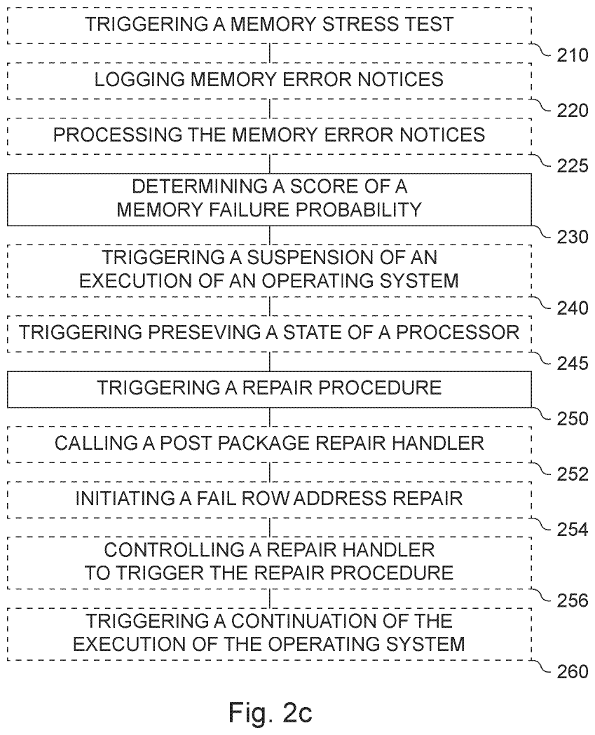

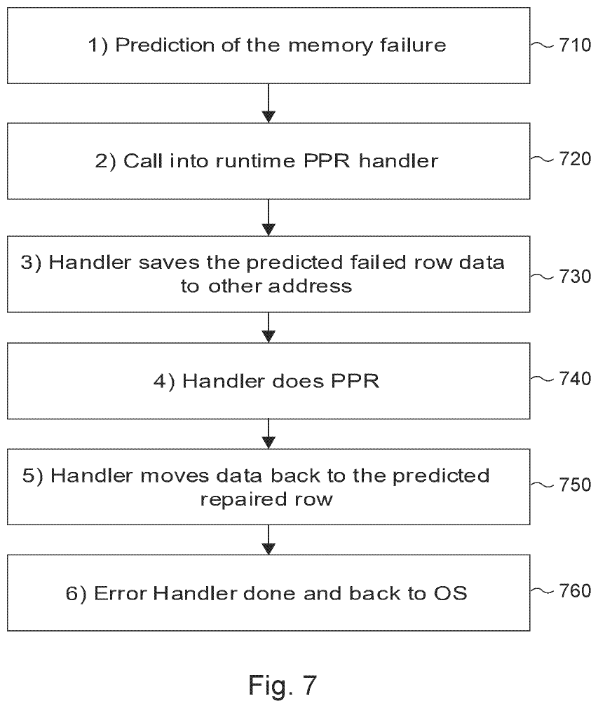

In general, hard memory failures are very rare. Moreover, the historical memory error dataset may comprise information on memory circuitry that was replaced once the first hard error has occurred. Therefore, fault data of subsequent faults (that would have occurred after the first memory fault) often is not available, as the memory circuitry was replaced before the second and subsequent memory failures could occur. For this reason, the training data being used for training the predictor may be biased, with only few of the logged errors being relevant to the (single) error that led to a replacement of the respective circuitry. Therefore, one or more rounds of weighting may be used to counteract the bias. For example, as shown in connection with FIGS. 3 and 8, a weighting may be performed to emphasize memory error samples. The trained predictor may be trained based on a weighted historical memory error dataset, with the weighting being performed to emphasize incorrectly classified samples and/or memory error samples.

In some examples, e.g., as shown in FIG. 8, additional measures may be taken to perform the weighting or to improve the effects of the weighting. As shown in FIG. 8, the predictor may comprise two components—a first set of machine-learning models 840 that are trained to determine so-called weak classifiers, and a second machine-learning model that is trained to provide the output of the predictor based on the weak classifiers. For example, the second machine-learning model may be trained using a variant of the AdaBoost algorithm, e.g., the AdaUBoost algorithm.

In some examples, a pre-existing memory failure prediction framework may be used as trained predictor, such as the Intel© Memory Failure Prediction (MFP) framework.

Once the score is determined, it may be used to determine, whether a repair procedure is to be triggered. The processing circuitry is configured to trigger the repair procedure of the at least one memory cell of the memory circuitry when the score reaches a threshold. In this context, the term “repair procedure” is used to indicate, that the memory circuitry is repaired in a manner that enables subsequent operation of the memory circuitry. However, memory failure is usually permanent, such that a repair of the actual failed circuits cannot be performed. Therefore, a repair includes a procedure where access to the failed memory is redirected to a previously unused spare portion of the memory circuitry that is used for repair purposes.

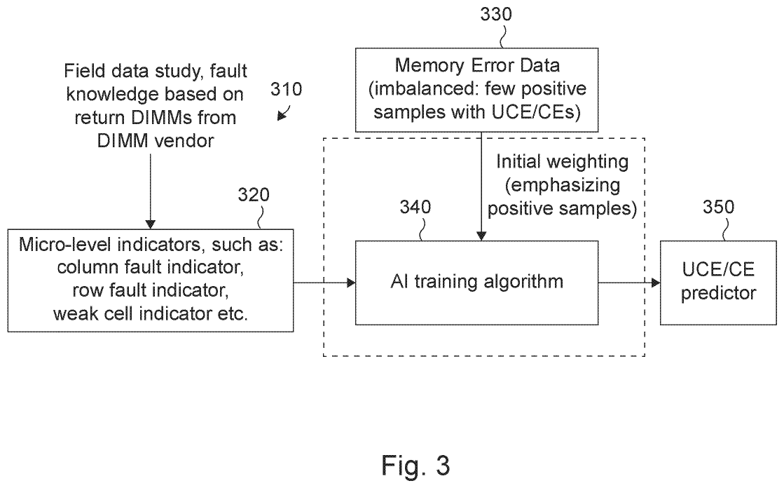

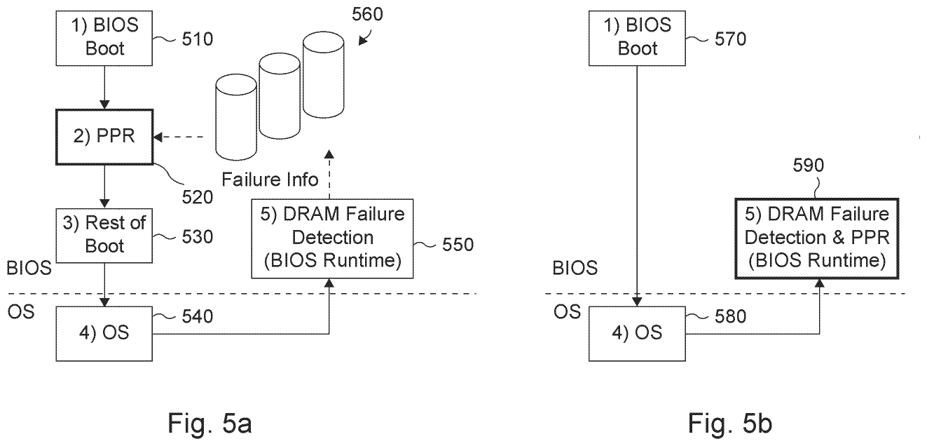

One scheme for doing this is called the Post Package Repair (PPR), which is illustrated in FIGS. 4 and 6. Accordingly, triggering the repair may include calling 252 (as shown in FIG. 1c) a PPR handler. In general, as defined in the JEDEC standard (a standard defined by the Joint Electron Device Engineering Council Solid State Technology Association) for DDR4 and DDR5 (Double Data Rate 4 and 5, respectively, which are DRAM standards), the PPR procedure is a procedure that is called during the boot process of the computing device, as a result of the Power-On Self-Test (POST) routine being used to check the health of the memory circuitry. However, the same process may be called after booting the computing device as well, i.e., at runtime. Accordingly, triggering the repair procedure may include calling 252 a runtime PPR handler. For example, the runtime PPR may be performed after power up boot operations have been completed. For example, the (runtime) PPR may be performed on a row comprising the at least one memory cell.

As outlined above, the actual memory circuitry often cannot be repaired. Therefore, access to the row comprising the at least one memory cell is redirected to a previously unused spare portion of the memory circuitry that is used for repair purposes. In PPR, this redirection is generally performed using an electrical fuse scheme. In the scheme, rows of so-called antifuses may be used. These antifuses initially have a high resistance. If a substantial voltage is applied to an antifuse, an electrically conductive path is formed (and thus the resistance is reduced), i.e., the antifuse is blown. Rows of such antifuses may be used to generate an additional input to an address decoder, with the initial input being used to overwrite addresses that point to the failed (or likely to fail) row of memory. In consequence, triggering the repair procedure may include initiating 254 (as further shown in FIG. 1c) a fail row address repair operation that uses an electrical fuse scheme (that “blows the fuse” on the antifuses being used to set the additional input to the address decoder). In effect, access to the failed (or rather likely to fail in the present case) row of memory is redirected to the spare row (denoted “Reserve for PPR” in FIGS. 4 and 6).

In various examples, the PPR may be managed by the SMI controller 204 of the computing device. In other words, the repair handler may be provided by the SMI controller 204. In this case, the processing circuitry may be configured to control the system management interrupt controller via the repair handler to trigger the repair procedure of the at least one memory cell of the memory circuitry when the score reaches the threshold. In other words, the processing circuitry of the control apparatus may be configured to control the system management interrupt controller via the repair handler provided by the SMI controller to trigger the repair procedure of the at least one memory cell of the memory circuitry when the score reaches a threshold. In this case, the post package repair handler or runtime post package repair handler is triggered by instructing the repair handler provided by a system management interrupt controller to perform the (runtime) post package repair procedure. Alternatively, the operating system may be configured to provide the repair handler for triggering the repair procedure. In this case, the processing circuitry may be configured to instruct the repair handler provided by the operating system to trigger the repair procedure of the at least one memory cell of the memory circuitry when the score reaches a threshold. In this case, the post package repair handler or runtime post package repair handler is triggered by instructing a repair handler provided by an operating system being hosted on a computing device comprising the control apparatus to perform a (runtime) post package repair procedure. In conclusion, the processing circuitry may be configured to instruct/control the repair handler, provided by the SMI controller or by the operating system, to trigger the repair procedure of the at least one memory cell of the memory circuitry when the score reaches a threshold. Accordingly, as further shown in FIG. 1c, the method may comprise controlling 256 a repair handler, provided by the system management interrupt controller or the operating system of the computing device, to trigger the repair procedure of the at least one memory cell of the memory circuitry when the score reaches a threshold. For example, the repair handler, provided by the system management interrupt controller or the operating system, may be configured to execute the runtime post package repair handler procedure, e.g., the fail row address repair operation using the electrical fuse scheme.

In various examples of the proposed concept, one aim is to enable a seamless repair procedure, i.e., without having downtime. For example, to avoid data loss, triggering the repair procedure may comprise copying the content of the at least one memory cell to the portion of spare memory to be used after the fail row address repair operation. Moreover, the Operating System (OS) being run on the computing device may be suspended (shortly, e.g., up to 50 microseconds) before the repair procedure and continued thereafter. In other words, the processing circuitry may be configured to trigger a suspension of an execution of an operating system before triggering the repair procedure, and to trigger a continuation of the execution of the operating system after the repair procedure. Accordingly, as further shown in FIG. 1c, the method may comprise triggering 240 the suspension of the execution of an operating system before triggering the repair procedure and triggering 260 the continuation of the execution of the operating system after the repair procedure. In addition, the state of the processors may be saved before the repair operation (and restored thereafter). For example, the processing circuitry is configured to trigger the preserving of a state of a processor in system management random access memory, SMRAM. Accordingly, the method may comprise triggering 245 the preserving of the state of a processor in the SMRAM.

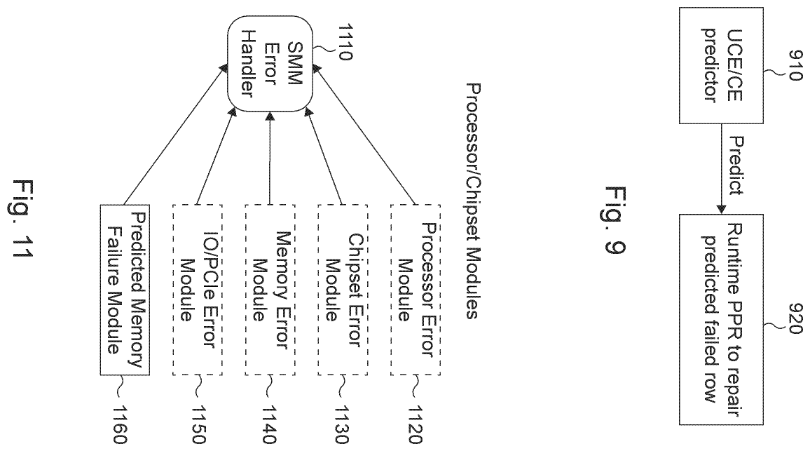

In some examples, the control apparatus 20 may be implemented as part of the Baseband Management Controller (BMC) firmware of the computing device, e.g., as shown in FIG. 10, where the MFP Engine 1052, which may correspond to the control apparatus 20, is hosted by the BMC firmware (FW). However, the BMC is often implemented using circuitry having limited processing power.

Instead, in some examples, the control apparatus may use the full power of the processing circuitry available in the computing device. For example, the control apparatus may be implemented as part of an operating system hosted by the computing system. In other words, the computing device may be configured to host an operating system. The operating system may, in turn, provide the functionality of the control apparatus. For example, the operating system may be configured to periodically perform the actions of the control apparatus, e.g., to periodically determine the score. For example, a task planning component of the operating system, such as a cronjob, may be used for this purpose.

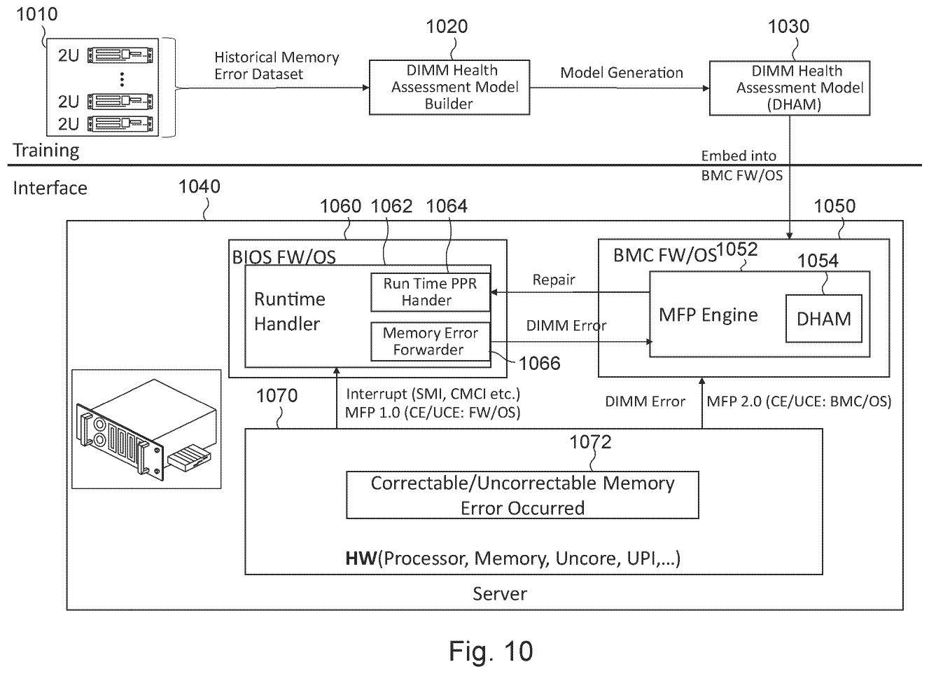

In some examples, as shown in FIG. 11, the proposed concept may be handled via a System Management Mode (SMM) of the one or more processors 206 of the computing device, accessing the one or more processors (e.g., Central Processing Units, CPUs) or other potent hardware of the computing device. For example, the one or more processors may be configured to provide the functionality of the control apparatus in a system management mode, SMM, or in a secure execution environment of the one or more processors. For example, the SMM error handler of the computing device may be extended to not only handle errors, such as memory errors, of the computing device, but also handle predicted memory failures. Therefore, the control apparatus 20 may implement the predicted memory failure module 1160 that is introduced in connection with FIG. 11. For example, the SMM error handler may be invoked periodically (e.g., every 6 hours, 12 hours, or every day), then yield to the control apparatus (being executed on processing circuitry of the computing device) to determine the score. If the score surpasses the threshold, the repair procedure may be triggered. By using the full breadth of hardware available at the computing device, the 50 ms runtime limit of the SMM error handler may be sufficient for running complex predictors, such as the predictor shown in FIG. 8. For example, accelerator circuitry of the computing device, such as a neural accelerator or graphics processing unit, may be used to run the predictor. In other words, the processing circuitry (being used to determine the score using the trained predictor) may comprise at least one of a central processing unit, an artificial intelligence chip, a neural network chip, a vector neural network instruction chip, and a deep learning chip. Accordingly, the method, e.g., the determining of the score, may be performed by at least one of a central processing unit, an artificial intelligence chip, a neural network chip, a vector neural network instruction chip, and a deep learning chip (of the computing device).

The interface circuitry 22 or means for communicating 22 of FIGS. 1a and 1b may correspond to one or more inputs and/or outputs for receiving and/or transmitting information, which may be in digital (bit) values according to a specified code, within a module, between modules or between modules of different entities. For example, the interface circuitry 22 or means for communicating 22 may comprise circuitry configured to receive and/or transmit information.

For example, the processing circuitry 24 or means for processing 24 of FIG. 1a or the one or more processors 206 of FIG. 1b may be implemented using one or more processing units, one or more processing devices, any means for processing, such as a processor, a computer or a programmable hardware component being operable with accordingly adapted software. In other words, the described function of the processing circuitry 24, means for processing 24 or one or more processors 206 may as well be implemented in software, which is then executed on one or more programmable hardware components. Such hardware components may comprise a general-purpose processor, a Digital Signal Processor (DSP), a microcontroller, etc.

In some examples, the memory circuitry 310 may include non-volatile and/or volatile types of memory. Non-volatile types of memory may include, but are not limited to, 3-dimensional cross-point memory, flash memory, ferroelectric memory, silicon-oxidenitride-oxide-silicon (SONOS) memory, polymer memory such as ferroelectric polymer memory, nanowire, ferroelectric transistor random access memory (FeTRAM or FeRAM), ovonic memory, nanowire or electrically erasable programmable read-only memory (EEPROM). Volatile types of memory may include, but are not limited to, dynamic random-access memory (DRAM) or static RAM (SRAM).

The computing device may be a computer, such as server computer, a workstation computer, a desktop computer, a mobile computer, such as a laptop computer, tablet computer or smartphone computer. In some examples, the computing device may be an embedded computer, such as an Internet-of-Things computing device or a sensor device.

Machine-learning algorithms are usually based on a machine-learning model. In other words, the term “machine-learning algorithm” may denote a set of instructions that may be used to create, train, or use a machine-learning model. The term “machine-learning model” may denote a data structure and/or set of rules that represents the learned knowledge, e.g., based on the training performed by the machine-learning algorithm. In embodiments, the usage of a machine-learning algorithm may imply the usage of an underlying machine-learning model (or of a plurality of underlying machine-learning models). The usage of a machine-learning model may imply that the machine-learning model and/or the data structure/set of rules that is the machine-learning model is trained by a machine-learning algorithm.

For example, the machine-learning model may be an artificial neural network (ANN). ANNs are systems that are inspired by biological neural networks, such as can be found in a brain. ANNs comprise a plurality of interconnected nodes and a plurality of connections, so-called edges, between the nodes. There are usually three types of nodes, input nodes that receiving input values, hidden nodes that are (only) connected to other nodes, and output nodes that provide output values. Each node may represent an artificial neuron. Each edge may transmit information, from one node to another. The output of a node may be defined as a (non-linear) function of the sum of its inputs. The inputs of a node may be used in the function based on a “weight” of the edge or of the node that provides the input. The weight of nodes and/or of edges may be adjusted in the learning process. In other words, the training of an artificial neural network may comprise adjusting the weights of the nodes and/or edges of the artificial neural network, i.e., to achieve a desired output for a given input. In at least some embodiments, the machine-learning model may be deep neural network, e.g., a neural network comprising one or more layers of hidden nodes (i.e., hidden layers), preferably a plurality of layers of hidden nodes.

Alternatively, the machine-learning model may be a support vector machine. Support vector machines (i.e., support vector networks) are supervised learning models with associated learning algorithms that may be used to analyze data, e.g., in classification or regression analysis. Support vector machines may be trained by providing an input with a plurality of training input values that belong to one of two categories. The support vector machine may be trained to assign a new input value to one of the two categories. Alternatively, the machine-learning model may be a Bayesian network, which is a probabilistic directed acyclic graphical model. A Bayesian network may represent a set of random variables and their conditional dependencies using a directed acyclic graph. Alternatively, the machine-learning model may be based on a genetic algorithm, which is a search algorithm and heuristic technique that mimics the process of natural selection.

More details and aspects of the control apparatus 20, control device 20, computing device 200, method and computer program are mentioned in connection with the proposed concept, or one or more examples described above or below (e.g., FIG. 1, 3 to 12). The control apparatus 20, control device 20, computing device 200, method and computer program may comprise one or more additional optional features corresponding to one or more aspects of the proposed concept, or one or more examples described above or below.

The proposed concept provides a methodology for potentially preventing memory failures by predicting the memory failure and repairing the DRAM hardware failure at runtime without data loss, performance, memory capacity and user impact. A prediction framework may be used to predict the impending failure of a portion of memory, with a prediction precision that can be upwards of 70%. For example, the Intel© Memory Failure Prediction (MFP) framework may be used to perform the prediction. The proposed concept may provide an effective feature for DRAM hard failure handling.

In summary, some approaches for handling memory errors result in hardware and service cost, system performance impact. If the memory failure can be predicted and the DRAM devices can be at runtime without or with little impact system performance, capacity loss, data loss and user impact, system stability, availability, and data safety may be improved, DIMM service time may be extended, and costs may be saved.

In a different concept, the aforementioned Runtime PPR is used to repair the memory at runtime based on runtime memory errors, i.e., when a hard failure has already occurred, which may potentially result in data loss. In the present concept, however, the failure of memory is predicted instead of (or in addition to) being detected, with the prediction being based on learning predictors that use field data, such as fault knowledge based on DIMMs returned to the vendor of the DIMM. Thus, the potential DRAM hard failure may be preemptively repaired before the failure occurs, without data loss.

Intel® MFP uses online machine learning to analyze the historical data collected on server memory down to the DIMM, bank, row, column, and cell level and gives a memory health score to predict potential future failures. Post Package Repair can correct Row per Bank Group. PPR provides simple and easy repair method in the system and the Fail Row address can be repaired by the electrical programming of an electrical-fuse scheme. Though the failure prediction precision is not 100% for now, there is no harm to the DRAM.

FIG. 3 shows a schematic diagram of a machine-learning based training of a predictor for predicting uncorrectable errors (UCEs) and/or correctable errors (CEs). In the training, data 310 of a field data study, fault knowledge on return DIMMs from a DIMM vendor are harvested to extract micro-level indicators 320, such as column fault indicators, row fault indicators, weak cell indicators etc. These micro-level indicators 320 are provided, together with memory error data 330) to an Artificial Intelligence (AI) training algorithm 340. However, the memory error data 330 may be imbalanced, with few positive samples (i.e., samples with UCEs/CEs). Therefore, an initial weighting may be performed when the memory error data 330 is provided to the AI training algorithm 340, emphasizing positive samples. The AI training algorithm yields the UCE/CE predictor 350.

The proposed concept takes advantage of memory failure prediction (MFP) and the PPR defined in the JEDEC standard and may enable a repair of potential DRAM hard failures at runtime before the failure is happening.

Memory failure prediction, such as Intel® MFP, may use online machine learning to analyze the historical data collected on server memory down to the DIMM, bank, row, column, and cell level and may yield a memory health score to predict potential future failures. In the JEDEC specification, the DDR4 and DDR5 standards support Failed Row address repair as optional feature (see FIG. 4), and Post Package Repair (PPR) provides a method that the Failed Row address can be repaired by the electrical programming of an electrical-fuse scheme. The proposed concept extends the PPR with respect to dynamic error handling, as shown in FIG. 6.

FIG. 4 shows a schematic diagram of Post Package Repair being triggered by a failed row in a memory device. FIG. 4 shows bank groups 0-4 (410; 430), with each bank group including or being associated with one or more rows 420; 440 that are reserved for PPR. In the example of FIG. 4, row 435 of bank group 1 430 has failed. Post package repair is used to redirect requests for failed row 435 to reserve 440.

FIG. 5a shows a schematic diagram of boot time PPR. In boot time PPR, after BIOS (Basic Input/Output System) boot 510, the PPR system 520 is invoked, (e.g., if the Power-On Self-Test, POST, has encountered failed memory), with the remainder of the boot process 530 and loading of the Operating System (OS) 540 following after the PPR procedure 520. The OS 540 triggers DRAM failure detection 550 (which is a BIOS operation performed at runtime), with failures being stored in a data storage 560, which is read out by the PPR component 520 at the next boot procedure.

FIG. 5b shows a schematic diagram of runtime PPR. In runtime PPR, the PPR procedure is generally not called during boot time, such that the bios boot 570 is not interrupted by the PPR procedure before loading the OS 580. If a DRAM failure is detected, the DRAM failure detection and PPR 590 (provided by the BIOS at runtime) are triggered.

In FIG. 6, a schematic diagram illustrates the application of memory failure prediction to runtime PPR. FIG. 4 shows bank groups 0-4 (610; 630), with each bank group including or being associated with one or more rows 620; 640 that are reserved for PPR. In contrast to the example of FIG. 4, the runtime PPR is not applied to a row after failure of said row but based on a prediction indicator to a row 635 that is predicted to fail. Post package repair is used to redirect requests for predicted failed row 435 to reserve 640.

The proposed concept uses the existing memory failure predication and PPR to predict the memory failure and do runtime repair of DRAM hard failure before the failure occurs, e.g., without capacity loss, data loss, performance impact, user impact and cost implication.

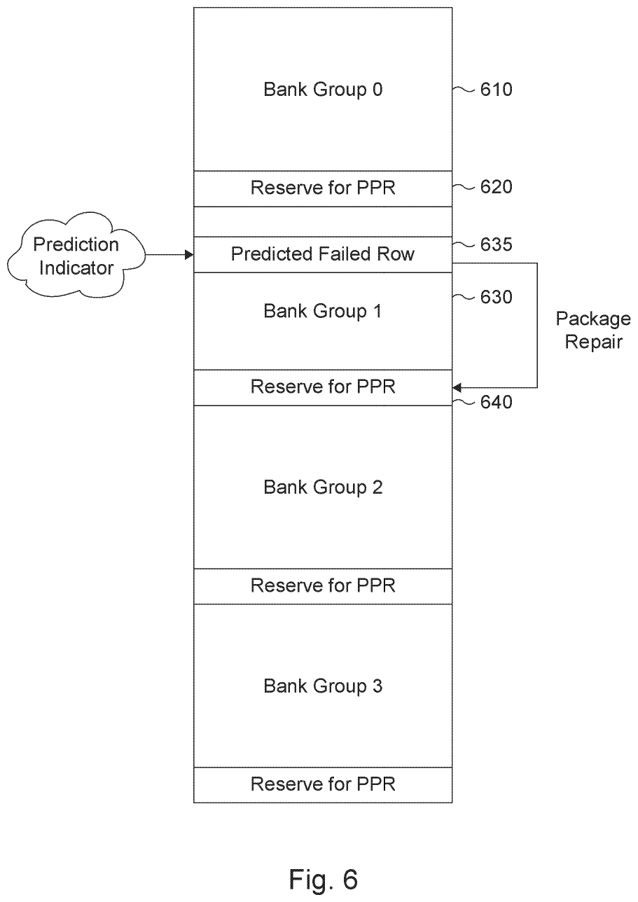

As shown in FIG. 4, in other concepts, PPR is activated when the memory failure is happening, so there is still the potential of data loss and user impact. The proposed concept, on the other hand, uses DRAM failure predication and runtime repairing and may thus prevent the data loss and user impact. For example, the following tasks may be performed by the proposed concept, as shown in FIG. 7. FIG. 7 shows a flow chart of an example of the proposed concept. FIG. 7 may show a DRAM failure predication and runtime PPR flow.

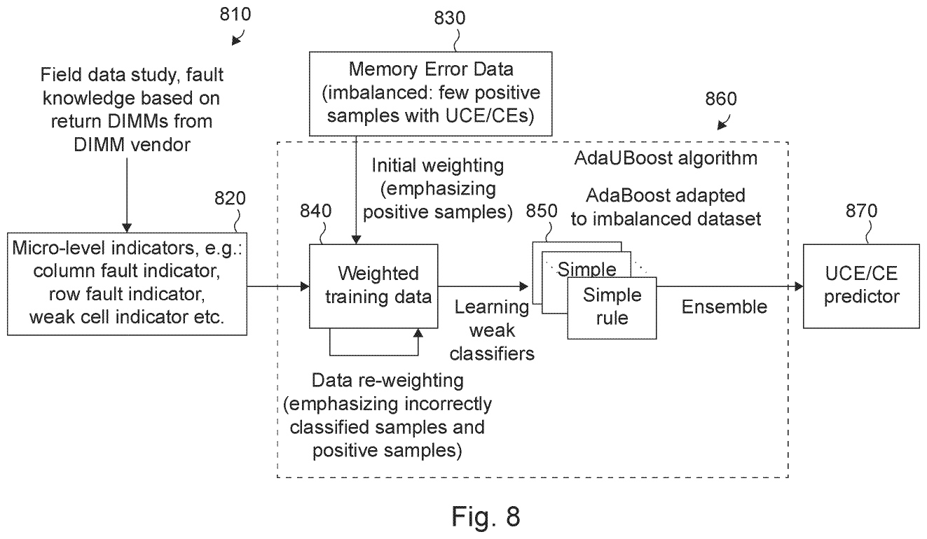

First, the memory failure may be predicted 710, e.g., using Intel© memory failure prediction. An example on how the prediction is performed, or rather how the predictor may be trained, is given in connection with FIG. 8. If an impending memory failure is predicted, a call may be made 720 into the runtime PPR handler (as shown in FIG. 9). The data of the row that is predicted fail failed may be saved 730, by the handler, to another address. Then the runtime PPR procedure may be performed 740 by the handler. Subsequently, the handler may move 750 the data back to the repaired row (replacing the predicted failed row). Then, the error handler is done and reverts 760 back to the OS. In the above flow, the potential memory hard failure may be repaired before the failure occurs, e.g., without data loss, and user impact.

FIG. 8 shows a schematic diagram of another example of machine-learning based training of a predictor for predicting uncorrectable errors (UCEs) and/or correctable errors (CEs) based on AdaUBoost, a variant of the AdaBoost algorithm. Similar to the example shown in FIG. 3, data 810 of a field data study, fault knowledge on return DIMMs from a DIMM vendor are harvested to extract micro-level indicators 820, such as column fault indicators, row fault indicators, weak cell indicators etc. These micro-level indicators 820 are provided, together with memory error data 830 to form training sets of weighted training data. Similar to FIG. 3, since the memory error data is imbalanced, an initial weighting of the memory error data may be performed. In addition, data re-weighting may be performed, further emphasizing incorrectly classified samples and positive samples. Based on the weighted training data, a plurality of weak classifiers are trained using machine-learning to yield a plurality of simple rules 850. These weak classifiers are used by the AdaUBoost algorithm, which is a variant of AdaBoost that is adapted to an imbalanced dataset, to create an enable, i.e., a machine-learning based transformation of the plurality of weak classifiers. Together, the weak classifiers and the transformation provided by the AdaUBoost algorithm yield the 870 predictor.

FIG. 9 shows a schematic diagram of a relationship between the UCE/CE predictor 910, which is used to predict the row about to fail, and the runtime PPR 920, which is used to repair the predicted failed row.

FIG. 10 shows a schematic diagram of an application of the proposed concept in a computer system. The schematic diagram distinguishes two components—the training of the predictor, which may occur outside the computer system, and the interface between the components implementing the proposed concept and the rest of the computer system. In the example shown in FIG. 10, for performing the training, a historical memory error dataset is collected from a plurality of servers 1010 and provided to a DIMM health assessment model builder 1020, which generates the machine-learning model to generate the 1030 DIMM health assessment model (DHAM), which concludes the training. In the computer system, e.g., server 1040, the DHAM is provided to the baseboard management controller firmware or the operating system 1050, which includes an MFP engine component 1052 (which may correspond to the control apparatus or device introduced in connection with FIG. 2a) that includes the DHAM 1054. Hardware 1070 (such as the processor, memory, uncore, Ultra Path Interconnect, UPI) of the server may determine that a correctable/uncorrectable memory error 1072 has occurred and may provide an interrupt, such as a system management interrupt (SMI) or a Corrected Machine Check Interrupt (CMCI), to a runtime handler 1062 (e.g., a repair handler or SMI handler) of a BIOS FW or the operating system 1060 of the server 1040 (MFP 1.0, CE/UCE: FW (e.g., BIOS) or OS). The interrupt may be provided once an uncorrectable error or a pre-defined number of correctable errors have occurred (e.g., within a row of the memory). The runtime handler 1062 may comprise a memory error forwarder 1066, which may forward DIMM errors to the MFT engine 1052. Alternatively (or additionally), the DIMM errors may be provided directly to the BMC FW or OS 1050, and thus the MFP engine 1052 (MFP 2.0, CE/UCE: BMC/OS). The MFP Engine 1052 may predict an impending failure of memory and trigger a runtime PPR handler 1064 of the BIOS FW or OS 1060 to repair the memory. In this context, both the components 1050 and 1060 may be jointly implemented by the OS of the server 1040. The term BIOS, as used herein, may refer to any type of host firmware, such as the BIOS FW or the Unified Extensible Firmware Interface (UEFI) FW.

In FIG. 10, the MFP engine component is integrated within the BMC FW or in the OS. However, in an alternative concept, the MFP engine component may be executed from a System Management Mode of the computer system, using the host processor of the computer system.

The proposed concept may provide a predictive failure analysis capability that uses long-range statistics via logs that may be stored in System Management RAM or in a Serial Peripheral Interface NOR flash and perform analytics, such as deep learning inference using an Instruction Set Architecture (ISA) like Intel© Deep Learning Boost or other XPU (X Processing Unit, with X denoting different types of accelerators) hardware (e.g., a special SMM (System Management Mode)-scoped mode/interface to a neural accelerator or an FPGA from an SMM error handler. For example, as shown in FIG. 11, the proposed predicted memory failure module 1160 (e.g., the control apparatus or device of FIG. 2a) may be coupled alongside error modules, such as a processor error module 1120, chipset error module 1130, memory error module 1140, I/O/Peripheral Component Interface express (PCIe) Error Module 1150 with the SMM error handler 1110. FIG. 11 shows a schematic overview of processor/chipset modules.

Running the proposed concept from SMM is different than running from within the OS since some of the error registers can be defined to require access control from SMM_EN (similar to S-Bit scoping access from ARM TrustZone for sequestered resources).

Running the proposed algorithm in the BMC (or another System-on-Chip microcontroller) may be limited by the comparatively low performance of the controller. The proposed algorithm may thus be run in SMM, which uses the host CPU (Central Processing Unit) resources and leverages the capabilities of the host ISA AI hardware.

The SMM may also be considered to be to ARM TrustZone (i.e., an OEM/platform-controlled OS independent mode) that may be exposed in some implementations of ARM-based processors, such that the proposed concept may be run in the ARM TrustZone as well. The proposed concept may use the ISA from SMM before operating systems or applications light up the ISA (geologic software enabling timeline versus velocity of BIOS enabling). In some examples, the XPU (FPGA (Field-Programmable Gate Array)/Artificial Intelligence accelerator/discrete Graphics Processing Unit) to be accessible from SMM for the proposed concept so that the respective XPUs can be leveraged when available without disrupting OS/hypervisor usage. The access to the capabilities of the XPU may also help overcome the limitations of SMM, where SMM events might only last 50 microseconds without disrupting the foreground OS—the increased computing power of the XPU may reduce the time required for running the algorithm. The same functionality may be exposed to the ARM TrustZone as well.

For example, the following inputs may be provided to the MFP engine—correctable errors (CE) data, uncorrectable errors (UCE) data, DIMM manufacture part data (such as vendor, date code, part number) and/or CPU model.

In general, there are multiple approaches to predict the memory errors which will possibly happen. For example, a pre-defined threshold may be reached at a number of correctable error happening on same or multiple memory locations. For example, pre-existing techniques may be used to report such errors from the BIOS to the OS via the memory RAS feature. Alternatively, or additionally, “suspicious” and spare memory spaces may be requested from the OS, and a stress memory test may be used to find out the weak cells, repair them and return to OS, and so forth to run another cycle prediction/check. In this context, “suspicious” may mean a space where the DIMM surface is hot, a space where the manufacturing data of the DIMM is older, or a DIMM was reworked or some rows/locations were repaired before, or DIMMs with particular data code and produced from particular vendors, etc. However, the prediction may be based on other types of prediction algorithms as well.

More details and aspects of the concept for me preventing memory failures by predicting the memory failure and repairing the DRAM hardware failure at runtime are mentioned in connection with the proposed concept or one or more examples described above or below (e.g., FIG. 1 to 2c). The concept for me preventing memory failures by predicting the memory failure and repairing the DRAM hardware failure at runtime may comprise one or more additional optional features corresponding to one or more aspects of the proposed concept, or one or more examples described above or below.

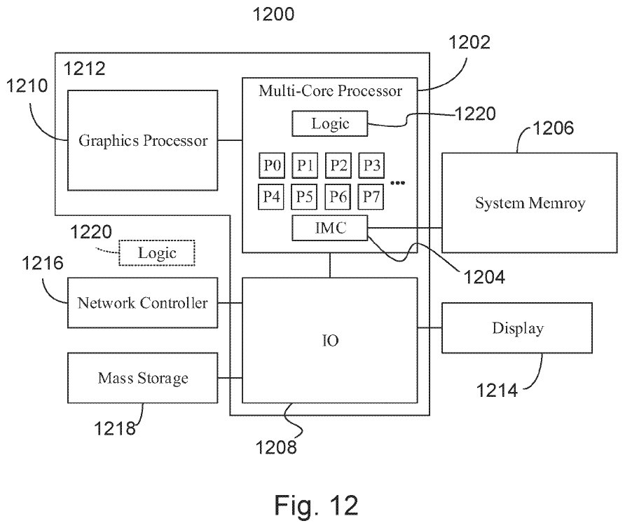

Turning now to FIG. 12, a computing system 1200 is shown, which may correspond to the computing device 200 of FIG. 2b. The computing system 1200 may generally be part of an electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), gaming functionality (e.g., networked multi-player console), etc., or any combination thereof. In the illustrated example, the system 1200 includes a multi-core processor 1202 (e.g., host processor (s), central processing unit (s)/CPU (s)) having an integrated memory controller (IMC) 1204 that is coupled to a system memory 1206. The multi-core processor 1202 may include a plurality of processor cores P0-P7.

The illustrated system 1200 also includes an input output (IO) module 1208 implemented together with the multi-core processor 1202 and a graphics processor 1210 on a semiconductor die 12122 as a system on chip (SoC). The illustrated IO module 1208 communicates with, for example, a display 1214 (e.g., touch screen, liquid crystal display/LCD, light emitting diode/LED display), a network controller 1216 (e.g., wired and/or wireless), and mass storage 1218 (e.g., hard disk drive/HDD, optical disk, solid state drive/SSD, flash memory).

The multi-core processor 1202 may include logic 1220 (e.g., logic instructions, configurable logic, fixed-functionality hardware logic, etc., or any combination thereof) to perform one or more aspects of the method of FIG. 2c and/or the method of FIG. 7, already discussed. Although the illustrated logic 1220 is located within the multi-core processor 1202, the logic 1220 may be located elsewhere in the computing system 1200.

More details and aspects of the computing system are mentioned in connection with the proposed concept, or one or more examples described above or below (e.g., FIG. 1 to 11). The computing system may comprise one or more additional optional features corresponding to one or more aspects of the proposed concept, or one or more examples described above or below.

In the following, some examples of the proposed concept are presented: An example (e.g., example 1) relates to a control apparatus (20) for managing repair of a memory circuitry (202), the control apparatus comprising processing circuitry (24) configured to determine a score of a memory failure probability of at least one memory cell of the memory circuitry (202). The processing circuitry is configured to trigger a repair procedure of the at least one memory cell of the memory circuitry when the score reaches a threshold.

Another example (e.g., example 2) relates to a previously described example (e.g., example 1) or to any of the examples described herein, further comprising that the processing circuitry is configured to log memory error notices from the memory circuitry, and to determine the score based on the memory error notices.

Another example (e.g., example 3) relates to a previously described example (e.g., one of the examples 1 to 2) or to any of the examples described herein, further comprising that the processing circuitry is configured to process memory error notices of the memory circuitry with a trained predictor to determine the score.

Another example (e.g., example 4) relates to a previously described example (e.g., example 3) or to any of the examples described herein, further comprising that the trained predictor is a trained machine-learning model.

Another example (e.g., example 5) relates to a previously described example (e.g., one of the examples 3 to 4) or to any of the examples described herein, further comprising that the trained predictor is trained based on a historical memory error dataset.

Another example (e.g., example 6) relates to a previously described example (e.g., example 5) or to any of the examples described herein, further comprising that the historical memory error dataset comprises fault data of failed memory circuits, the fault data comprising fault location data.

Another example (e.g., example 7) relates to a previously described example (e.g., one of the examples 5 to 6) or to any of the examples described herein, further comprising that the trained predictor is trained based on a weighted historical memory error dataset, with the weighting being performed to emphasize incorrectly classified samples and/or memory error samples.

Another example (e.g., example 8) relates to a previously described example (e.g., one of the examples 1 to 7) or to any of the examples described herein, further comprising that the processing circuitry is configured to determine the score based on at least one of a temperature of the memory circuitry, a number of errors, a number of correctable errors, a number of uncorrectable errors, a manufacturing data of the memory circuitry, and a repair history of the memory circuitry.

Another example (e.g., example 9) relates to a previously described example (e.g., one of the examples 1 to 8) or to any of the examples described herein, further comprising that the score is associated with a memory location of the memory circuitry and the memory location is identified by at least one of a Dual Inline Memory Module, DIMM, identifier, a bank, a row, a column, and a cell.

Another example (e.g., example 10) relates to a previously described example (e.g., one of the examples 1 to 9) or to any of the examples described herein, further comprising that triggering the repair includes calling a post package repair handler.

Another example (e.g., example 11) relates to a previously described example (e.g., one of the examples 1 to 10) or to any of the examples described herein, further comprising that triggering the repair procedure includes calling a runtime post package repair handler.

Another example (e.g., example 12) relates to a previously described example (e.g., one of the examples 10 to 11) or to any of the examples described herein, further comprising that the post package repair handler or runtime post package repair handler is triggered by instructing a repair handler provided by a system management interrupt controller to perform a post package repair procedure.

Another example (e.g., example 13) relates to a previously described example (e.g., one of the examples 10 to 11) or to any of the examples described herein, further comprising that the post package repair handler or runtime post package repair handler is triggered by instructing a repair handler provided by an operating system being hosted on a computing device comprising the control apparatus to perform a post package repair procedure. Another example (e.g., example 14) relates to a previously described example (e.g., one of the examples 1 to 13) or to any of the examples described herein, further comprising that triggering the repair procedure includes initiating a fail row address repair operation that uses an electrical fuse scheme.

Another example (e.g., example 15) relates to a previously described example (e.g., one of the examples 1 to 14) or to any of the examples described herein, further comprising that the processing circuitry is configured to trigger a memory stress test of the memory circuitry, and to determine the score based on memory error notices generated during or after the memory stress test.

Another example (e.g., example 16) relates to a previously described example (e.g., one of the examples 1 to 15) or to any of the examples described herein, further comprising that the processing circuitry is configured to trigger a suspension of an execution of an operating system before triggering the repair procedure, and to trigger a continuation of the execution of the operating system after the repair procedure.

Another example (e.g., example 17) relates to a previously described example (e.g., example 16) or to any of the examples described herein, further comprising that the processing circuitry is configured to trigger the preserving of a state of a processor in system management random access memory, SMRAM.

Another example (e.g., example 18) relates to a previously described example (e.g., one of the examples 1 to 17) or to any of the examples described herein, further comprising that the processing circuitry comprises at least one of a central processing unit, an artificial intelligence chip, a neural network chip, a vector neural network instruction chip, and a deep learning chip.

An example (e.g., example 19) relates to a computing device (200), comprising a memory circuitry (202), and the control apparatus (20) according to one of the examples 1 to 18 or according to any other example.

Another example (e.g., example 20) relates to a previously described example (e.g., example 19) or to any of the examples described herein, further comprising that the computing device comprises a system management interrupt controller (204), wherein the system management interrupt controller (204) is configured to provide a repair handler for triggering the repair procedure, wherein the processing circuitry of the control apparatus is configured to control the system management interrupt controller via the repair handler to trigger the repair procedure of the at least one memory cell of the memory circuitry when the score reaches a threshold.

Another example (e.g., example 21) relates to a previously described example (e.g., example 19) or to any of the examples described herein, further comprising that the computing device is configured to host an operating system, wherein the operating system is configured to provide a repair handler for triggering the repair procedure, wherein the processing circuitry of the control apparatus is configured to instruct the repair handler provided by the operating system to trigger the repair procedure of the at least one memory cell of the memory circuitry when the score reaches a threshold.

Another example (e.g., example 22) relates to a previously described example (e.g., one of the examples 19 to 20) or to any of the examples described herein, further comprising that the repair handler is configured to execute a post package repair handler procedure.

Another example (e.g., example 23) relates to a previously described example (e.g., one of the examples 19 to 20) or to any of the examples described herein, further comprising that the repair handler is configured to execute a runtime post package repair handler procedure.

Another example (e.g., example 24) relates to a previously described example (e.g., one of the examples 19 to 23) or to any of the examples described herein, further comprising that the repair handler is configured to perform a fail row address repair operation using an electrical fuse scheme.

Another example (e.g., example 25) relates to a previously described example (e.g., one of the examples 19 to 24) or to any of the examples described herein, further comprising that the computing device is configured to host an operating system, wherein the operating system is configured to provide the functionality of the control apparatus.

Another example (e.g., example 26) relates to a previously described example (e.g., one of the examples 19 to 25) or to any of the examples described herein, comprising one or more processors (206) implementing the processing circuitry of the control apparatus, wherein the one or more processors are configured to provide the functionality of the control apparatus in a system management mode, SMM, or in a secure execution environment of the one or more processors.

An example (e.g., example 27) relates to a control device (20) for managing repair of a memory circuitry (202), the control device comprising means for processing (24) configured to determine a score of a memory failure probability of at least one memory cell of the memory circuitry (202). The means for processing is configured to trigger a repair procedure of the at least one memory cell of the memory circuitry when the score reaches a threshold.

Another example (e.g., example 28) relates to a previously described example (e.g., example 27) or to any of the examples described herein, further comprising that the means for processing is configured to log memory error notices from the memory circuitry, and to determine the score based on the memory error notices.

Another example (e.g., example 29) relates to a previously described example (e.g., one of the examples 27 to 28) or to any of the examples described herein, further comprising that the means for processing is configured to process memory error notices of the memory circuitry with a trained predictor to determine the score.

Another example (e.g., example 30) relates to a previously described example (e.g., example 29) or to any of the examples described herein, further comprising that the trained predictor is a trained machine-learning model.

Another example (e.g., example 31) relates to a previously described example (e.g., one of the examples 29 to 30) or to any of the examples described herein, further comprising that the trained predictor is trained based on a historical memory error dataset.

Another example (e.g., example 32) relates to a previously described example (e.g., example 31) or to any of the examples described herein, further comprising that the historical memory error dataset comprises fault data of failed memory circuits, the fault data comprising fault location data.

Another example (e.g., example 33) relates to a previously described example (e.g., one of the examples 31 to 32) or to any of the examples described herein, further comprising that the trained predictor is trained based on a weighted historical memory error dataset, with the weighting being performed to emphasize incorrectly classified samples and/or memory error samples.

Another example (e.g., example 34) relates to a previously described example (e.g., one of the examples 27 to 33) or to any of the examples described herein, further comprising that the means for processing is configured to determine the score based on at least one of a temperature of the memory circuitry, a number of errors, a number of correctable errors, a number of uncorrectable errors, a manufacturing data of the memory circuitry, and a repair history of the memory circuitry.

Another example (e.g., example 35) relates to a previously described example (e.g., one of the examples 27 to 34) or to any of the examples described herein, further comprising that the score is associated with a memory location of the memory circuitry and the memory location is identified by at least one of a Dual Inline Memory Module, DIMM, identifier, a bank, a row, a column, and a cell.

Another example (e.g., example 36) relates to a previously described example (e.g., one of the examples 27 to 35) or to any of the examples described herein, further comprising that triggering the repair includes calling a post package repair handler.

Another example (e.g., example 37) relates to a previously described example (e.g., one of the examples 27 to 36) or to any of the examples described herein, further comprising that triggering the repair procedure includes calling a runtime post package repair handler.

Another example (e.g., example 38) relates to a previously described example (e.g., one of the examples 27 to 37) or to any of the examples described herein, further comprising that triggering the repair procedure includes initiating a fail row address repair operation that uses an electrical fuse scheme.

Another example (e.g., example 39) relates to a previously described example (e.g., one of the examples 37 to 38) or to any of the examples described herein, further comprising that the post package repair handler or runtime post package repair handler is triggered by instructing a repair handler provided by a system management interrupt controller to perform a post package repair procedure.

Another example (e.g., example 40) relates to a previously described example (e.g., one of the examples 37 to 38) or to any of the examples described herein, further comprising that the post package repair handler or runtime post package repair handler is triggered by instructing a repair handler provided by an operating system being hosted on a computing device comprising the control apparatus to perform a post package repair procedure.

Another example (e.g., example 41) relates to a previously described example (e.g., one of the examples 27 to 40) or to any of the examples described herein, further comprising that the means for processing is configured to trigger a memory stress test of the memory circuitry, and to determine the score based on memory error notices generated during or after the memory stress test.

Another example (e.g., example 42) relates to a previously described example (e.g., one of the examples 37 to 41) or to any of the examples described herein, further comprising that the means for processing is configured to trigger a suspension of an execution of an operating system before triggering the repair procedure, and to trigger a continuation of the execution of the operating system after the repair procedure.

Another example (e.g., example 43) relates to a previously described example (e.g., example 42) or to any of the examples described herein, further comprising that the means for processing is configured to trigger the preserving of a state of a processor in system management random access memory, SMRAM.

Another example (e.g., example 44) relates to a previously described example (e.g., one of the examples 27 to 43) or to any of the examples described herein, further comprising that the means for processing comprises at least one of a central processing unit, an artificial intelligence chip, a neural network chip, a vector neural network instruction chip, and a deep learning chip.

An example (e.g., example 45) relates to a computing device (200), comprising a memory circuitry (202), and the control device (20) according to one of the examples 27 to 44 or according to any other example.

Another example (e.g., example 46) relates to a previously described example (e.g., example 45) or to any of the examples described herein, further comprising that the computing device comprises a system management interrupt controller (204), wherein the system management interrupt controller (204) is configured to provide a repair handler for triggering the repair procedure, wherein the means for processing of the control device is configured to control the system management interrupt controller via the repair handler to trigger the repair procedure of the at least one memory cell of the memory circuitry when the score reaches a threshold.

Another example (e.g., example 47) relates to a previously described example (e.g., example 46) or to any of the examples described herein, further comprising that the computing device is configured to host an operating system, wherein the operating system is configured to provide a repair handler for triggering the repair procedure, wherein the means for processing of the control device is configured to instruct the repair handler provided by the operating system to trigger the repair procedure of the at least one memory cell of the memory circuitry when the score reaches a threshold.

Another example (e.g., example 48) relates to a previously described example (e.g., one of the examples 46 to 47) or to any of the examples described herein, further comprising that the system repair handler is configured to execute a post package repair handler procedure.

Another example (e.g., example 49) relates to a previously described example (e.g., one of the examples 46 to 47) or to any of the examples described herein, further comprising that the repair handler is configured to execute a runtime post package repair handler procedure.

Another example (e.g., example 50) relates to a previously described example (e.g., one of the examples 46 to 49) or to any of the examples described herein, further comprising that the repair handler is configured to perform a fail row address repair operation using an electrical fuse scheme.

Another example (e.g., example 51) relates to a previously described example (e.g., one of the examples 19 to 24) or to any of the examples described herein, further comprising that the computing device is configured to host an operating system, wherein the operating system is configured to provide the functionality of the control apparatus.

Another example (e.g., example 52) relates to a previously described example (e.g., one of the examples 45 to 51) or to any of the examples described herein, comprising one or more processors (206) implementing the means for processing of the control device, wherein the one or more processors are configured to provide the functionality of the control device in a system management mode, SMM, or in a secure execution environment of the one or more processors.

An example (e.g., example 53) relates to a method for managing repair of a memory circuitry, the method comprising determining (230) a score of a memory failure probability of at least one memory cell of the memory circuitry. The method comprises triggering (250) a repair procedure of the at least one memory cell of the memory circuitry when the score reaches a threshold.

Another example (e.g., example 54) relates to a previously described example (e.g., example 53) or to any of the examples described herein, further comprising that the method comprises logging (220) memory error notices from the memory circuitry and determining (230) the score based on the memory error notices.

Another example (e.g., example 55) relates to a previously described example (e.g., one of the examples 53 to 54) or to any of the examples described herein, further comprising that the method comprises processing (225) memory error notices of the memory circuitry with a trained predictor to determine the score.

Another example (e.g., example 56) relates to a previously described example (e.g., example 55) or to any of the examples described herein, further comprising that the trained predictor is a trained machine-learning model.

Another example (e.g., example 57) relates to a previously described example (e.g., one of the examples 55 to 56) or to any of the examples described herein, further comprising that the trained predictor is trained based on a historical memory error dataset.

Another example (e.g., example 58) relates to a previously described example (e.g., example 57) or to any of the examples described herein, further comprising that the historical memory error dataset comprises fault data of failed memory circuits, the fault data comprising fault location data.

Another example (e.g., example 59) relates to a previously described example (e.g., one of the examples 57 to 58) or to any of the examples described herein, further comprising that the trained predictor is trained based on a weighted historical memory error dataset, with the weighting being performed to emphasize incorrectly classified samples and/or memory error samples.

Another example (e.g., example 60) relates to a previously described example (e.g., one of the examples 53 to 59) or to any of the examples described herein, further comprising that the method comprises determining (230) the score based on at least one of a temperature of the memory circuitry, a number of errors, a number of correctable errors, a number of uncorrectable errors, a manufacturing data of the memory circuitry, and a repair history of the memory circuitry.

Another example (e.g., example 61) relates to a previously described example (e.g., one of the examples 53 to 60) or to any of the examples described herein, further comprising that the score is associated with a memory location of the memory circuitry and the memory location is identified by at least one of a Dual Inline Memory Module, DIMM, identifier, a bank, a row, a column, and a cell.

Another example (e.g., example 62) relates to a previously described example (e.g., one of the examples 53 to 61) or to any of the examples described herein, further comprising that triggering (250) the repair includes calling (252) a post package repair handler.

Another example (e.g., example 63) relates to a previously described example (e.g., one of the examples 53 to 62) or to any of the examples described herein, further comprising that triggering the repair procedure includes calling (252) a runtime post package repair handler.

Another example (e.g., example 64) relates to a previously described example (e.g., one of the examples 62 to 63) or to any of the examples described herein, further comprising that the post package repair handler or runtime post package repair handler is triggered by instructing a repair handler provided by a system management interrupt controller to perform a post package repair procedure.

Another example (e.g., example 65) relates to a previously described example (e.g., one of the examples 62 to 63) or to any of the examples described herein, further comprising that the post package repair handler or runtime post package repair handler is triggered by instructing a repair handler provided by an operating system being hosted on a computing device comprising the control apparatus to perform a post package repair procedure.

Another example (e.g., example 66) relates to a previously described example (e.g., one of the examples 53 to 65) or to any of the examples described herein, further comprising that triggering the repair procedure includes initiating (254) a fail row address repair operation that uses an electrical fuse scheme.

Another example (e.g., example 67) relates to a previously described example (e.g., one of the examples 53 to 66) or to any of the examples described herein, further comprising that the method comprises triggering (210) a memory stress test of the memory circuitry and determining (230) the score based on memory error notices generated during or after the memory stress test.

Another example (e.g., example 68) relates to a previously described example (e.g., one of the examples 53 to 67) or to any of the examples described herein, further comprising that the method comprises triggering (240) a suspension of an execution of an operating system before triggering the repair procedure and triggering (260) a continuation of the execution of the operating system after the repair procedure.

Another example (e.g., example 69) relates to a previously described example (e.g., example 68) or to any of the examples described herein, further comprising that the method comprises triggering (245) the preserving of a state of a processor in system management random access memory, SMRAM.

Another example (e.g., example 70) relates to a previously described example (e.g., one of the examples 53 to 69) or to any of the examples described herein, further comprising that the method is performed by at least one of a central processing unit, an artificial intelligence chip, a neural network chip, a vector neural network instruction chip, and a deep learning chip.

An example (e.g., example 71) relates to a computing device comprising memory circuitry, the computing device being configured to perform the method according to one of the examples 53 to 70 or according to any other example.

Another example (e.g., example 72) relates to a previously described example (e.g., example 71) or to any of the examples described herein, further comprising that the method comprises controlling (256) a repair handler provided by a system management interrupt controller of the computing device to trigger the repair procedure of the at least one memory cell of the memory circuitry when the score reaches a threshold.

Another example (e.g., example 73) relates to a previously described example (e.g., example 71) or to any of the examples described herein, further comprising that the method comprises controlling (256) a repair handler provided by an operating system hosted by the computing device to trigger the repair procedure of the at least one memory cell of the memory circuitry when the score reaches a threshold.

Another example (e.g., example 74) relates to a previously described example (e.g., one of the examples 72 to 73) or to any of the examples described herein, further comprising that the repair handler a post package repair handler procedure.

Another example (e.g., example 75) relates to a previously described example (e.g., one of the examples 72 to 73) or to any of the examples described herein, further comprising that the repair handler executes a runtime post package repair handler procedure.

Another example (e.g., example 76) relates to a previously described example (e.g., one of the examples 72 to 75) or to any of the examples described herein, further comprising that the repair handler executes a fail row address repair operation using an electrical fuse scheme.

Another example (e.g., example 77) relates to a previously described example (e.g., one of the examples 71 to 76) or to any of the examples described herein, further comprising that the computing device is configured to host an operating system, wherein the operating system is configured to perform the method according to one of the examples 53 to 70 or according to any other example.

Another example (e.g., example 78) relates to a previously described example (e.g., one of the examples 71 to 77) or to any of the examples described herein, comprising one or more processors (206), wherein the one or more processors perform the method according to one of the claims 45 to 60 or according to any other example in a system management mode, SMM, or in a secure execution environment of the one or more processors.

An example (e.g., example 79) relates to a machine-readable storage medium including program code, when executed, to cause a machine to perform the method of one of the examples 53 to 70 or according to any other example.

An example (e.g., example 80) relates to a computer program having a program code for performing the method of one of the examples 53 to 70 or according to any other example when the computer program is executed on a computer, a processor, or a programmable hardware component.

An example (e.g., example 81) relates to a machine-readable storage including machine readable instructions, when executed, to implement a method or realize an apparatus as claimed in any pending claim or shown in any example.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor, or other programmable hardware component. Thus, steps, operations, or processes of different ones of the methods described above may also be executed by programmed computers, processors, or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations, or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process, or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

As used herein, the term “module” refers to logic that may be implemented in a hardware component or device, software or firmware running on a processing unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processing units, state machine circuitry, and/or firmware that stores instructions executable by programmable circuitry. Modules described herein may, collectively or individually, be embodied as circuitry that forms a part of a computing system. Thus, any of the modules can be implemented as circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processing units capable of executing computer-executable instructions to perform any of the disclosed methods. As used herein, the term “computer” refers to any computing system or device described or mentioned herein. Thus, the term “computer-executable instruction” refers to instructions that can be executed by any computing system or device described or mentioned herein.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based examples (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

The disclosed methods, control apparatuses, and systems are not to be construed as limiting in any way. Instead, the present disclosure is directed toward all novel and nonobvious features and aspects of the various disclosed examples, alone and in various combinations and subcombinations with one another. The disclosed methods, control apparatuses, and systems are not limited to any specific aspect or feature or combination thereof, nor do the disclosed examples require that any one or more specific advantages be present, or problems be solved.

Theories of operation, scientific principles, or other theoretical descriptions presented herein in reference to the control apparatuses or methods of this disclosure have been provided for the purposes of better understanding and are not intended to be limiting in scope. The control apparatuses and methods in the appended claims are not limited to those control apparatuses and methods that function in the manner described by such theories of operation.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. A control apparatus for managing repair of a memory circuitry, the control apparatus comprising interface circuitry and processing circuitry to:
determine a score of a memory failure probability of at least one memory cell of the memory circuitry; and
trigger a repair procedure of the at least one memory cell of the memory circuitry when the score reaches a threshold.

2. The control apparatus according to claim 1, wherein the processing circuitry is to log memory error notices from the memory circuitry, and to determine the score based on the memory error notices.

3. The control apparatus according to claim 1, wherein the processing circuitry is to process memory error notices of the memory circuitry with a trained predictor to determine the score.

4. The control apparatus according to claim 3, wherein the trained predictor is a trained machine-learning model.

5. The control apparatus according to claim 3, wherein the trained predictor is trained based on a historical memory error dataset.

6. The control apparatus according to claim 5, wherein the historical memory error dataset comprises fault data of failed memory circuits, the fault data comprising fault location data.

7. The control apparatus according to claim 5, wherein the trained predictor is trained based on a weighted historical memory error dataset, with the weighting being performed to emphasize incorrectly classified samples and/or memory error samples.

8. The control apparatus according to claim 1, wherein the processing circuitry is to determine the score based on at least one of a temperature of the memory circuitry, a number of errors, a number of correctable errors, a number of uncorrectable errors, a manufacturing data of the memory circuitry, and a repair history of the memory circuitry.

9. The control apparatus according to claim 1, wherein the score is associated with a memory location of the memory circuitry and the memory location is identified by at least one of a Dual Inline Memory Module (DIMM) identifier, a bank, a row, a column, and a cell.

10. The control apparatus according to claim 1, wherein triggering the repair includes calling a post package repair handler or a runtime post package repair handler.

11. The control apparatus according to claim 10, wherein the post package repair handler or runtime post package repair handler is triggered by instructing a repair handler provided by a system management interrupt controller to perform a post package repair procedure.

12. The control apparatus according to claim 10, wherein the post package repair handler or runtime post package repair handler is triggered by instructing a repair handler provided by an operating system being hosted on a computing device comprising the control apparatus to perform a post package repair procedure.

13. The control apparatus according to claim 1, wherein triggering the repair procedure includes initiating a fail row address repair operation that uses an electrical fuse scheme.

14. The control apparatus according to claim 1, wherein the processing circuitry is to trigger a memory stress test of the memory circuitry, and to determine the score based on memory error notices generated during or after the memory stress test.

15. The control apparatus according to claim 1, wherein the processing circuitry is to trigger a suspension of an execution of an operating system before triggering the repair procedure, and to trigger a continuation of the execution of the operating system after the repair procedure.

16. The control apparatus according to claim 15, wherein the processing circuitry is to trigger the preserving of a state of a processor in system management random access memory (SMRAM).

17. The control apparatus according to claim 1, wherein the processing circuitry comprises at least one of a central processing unit, an artificial intelligence chip, a neural network chip, a vector neural network instruction chip, and a deep learning chip.

18. A computing device, comprising:
a memory circuitry, and
the control apparatus according to claim 1.

19. The computing device according to claim 18, wherein the computing device comprises a system management interrupt controller, wherein the system management interrupt controller is to provide a repair handler for triggering the repair procedure, wherein the processing circuitry of the control apparatus is to control the system management interrupt controller via the repair handler to trigger the repair procedure of the at least one memory cell of the memory circuitry when the score reaches a threshold.

20. The computing device according to claim 18, wherein the computing device is to host an operating system, wherein the operating system is to provide a repair handler for triggering the repair procedure, wherein the processing circuitry of the control apparatus is to instruct the repair handler provided by the operating system to trigger the repair procedure of the at least one memory cell of the memory circuitry when the score reaches a threshold.

21. The computing device according to claim 18, wherein the computing device is to host an operating system, wherein the operating system is to provide the functionality of the control apparatus.

22. The computing device according to claim 18, comprising one or more processors implementing the processing circuitry of the control apparatus, wherein the one or more processors are to provide the functionality of the control apparatus in a system management mode (SMM) or in a secure execution environment of the one or more processors.

23. A method for managing repair of a memory circuitry, the method comprising:
determining a score of a memory failure probability of at least one memory cell of the memory circuitry; and
triggering a repair procedure of the at least one memory cell of the memory circuitry when the score reaches a threshold.

24. A machine-readable storage medium including program code, when executed, to cause a machine to perform the method of claim 23.
